(19) United States
(12) Patent Application Publication
(10) Pub. No.: US 2025/0379096 A1
(43) Pub. Date: Dec. 11, 2025

(54) EDGE RING CONFIGURATIONS FOR PROCESSING CHAMBERS AND RELATED CHAMBER KITS AND METHODS

(71) Applicant: Applied Materials, Inc., Santa Clara, CA (US)

(72) Inventors: Raja Murali DHAMODHARAN, Madurai (IN); Shu-Kwan LAU, Sunnyvale, CA (US); Zuoming ZHU, Sunnyvale, CA (US); Kalaivanan MOHANADASS, Santa Clara, CA (US); Aniketnitin PATIL, San Jose, CA (US)

(21) Appl. No.: 18/738,960

(22) Filed: Jun. 10, 2024

(51) Int. Cl. H01L 21/687; C23C 16/46; C23C 16/458; C30B 25/10; C30B 25/12; C30B 25/14; H01L 21/02

(52) U.S. Cl. CPC H01L 21/68735; C23C 16/46; C23C 16/4585; C30B 25/10; C30B 25/12; C30B 25/14; H01L 21/02532

(57) ABSTRACT

Embodiments of the present disclosure relate to multi-section substrate supports, and related process kits, processing chambers, components, and methods for semiconductor manufacturing. In one or more embodiments, a processing chamber includes a chamber body, one or more heat sources, a support, and an edge ring. The chamber body includes a processing volume, one or more gas inject passages formed in the chamber body, and one or more gas exhaust passages formed in the chamber body. The one or more heat sources are operable to heat the processing volume. The support is disposed in the processing volume, and the edge ring is at least partially supported by the support. The edge ring includes an annular section, and a shoulder abutting against the support to position the annular section at a gap from the support. The edge ring defines an inner portion that is sized and shaped to support a substrate.

### BACKGROUND

### FIELD

Embodiments of the present disclosure generally relate to processing chambers, methods, and process kits with multi-section substrate supports for semiconductor manufacturing. In one or more embodiments, a processing chamber includes a chamber body, one or more heat sources, a support, and an edge ring.

### DESCRIPTION OF THE RELATED ART

Semiconductor substrates are processed for a wide variety of applications, including the fabrication of integrated devices and micro-devices. One method of processing substrates includes depositing a material, such as a dielectric material or a semiconductor material, on an upper surface of the substrate. The material may be deposited in a lateral flow chamber by flowing a process gas parallel to the surface of a substrate positioned on a support, and thermally decomposing the process gas to deposit a material from the gas onto the substrate surface.

However, operations (such as epitaxial deposition operations) can be long, expensive, and inefficient, and can have limited capacity and throughput. Moreover, hardware can involve relatively large dimensions that occupy higher footprints in manufacturing facilities. Additionally, processing can involve non-uniformities, which can involve hindered device performance and/or reduced throughput. For example, components can pull heat away or localize heat within the processing volume, which causes non-uniformities and lowers deposition quality. As an example, heat flowing away from the substrate can cause deposition non-uniformity, such as edge roll-off and deposition slip lines. Such issues can be exacerbated in batch processing operations.

Therefore, a need exists for improved apparatuses and methods in semiconductor processing.

### SUMMARY

Embodiments of the present disclosure relate to multi-section substrate supports, and related process kits, processing chambers, components, and methods for semiconductor manufacturing.

In one or more embodiments, a processing chamber includes a chamber body, one or more heat sources, a support, and an edge ring. The chamber body includes a processing volume, one or more gas inject passages formed in the chamber body, and one or more gas exhaust passages formed in the chamber body. The one or more heat sources are operable to heat the processing volume. The support is disposed in the processing volume, and the edge ring is at least partially supported by the support. The edge ring includes an annular section, and a shoulder abutting against the support to position the annular section at a gap from the support. The edge ring defines an inner portion that is sized and shaped to support a substrate.

In one or more embodiments, a chamber kit applicable for semiconductor manufacturing is provided. The chamber kit includes a support and an edge ring. The edge ring is sized and shaped for disposition on the support and includes a shoulder, and inner shelf extending radially inward of the shoulder, and an annular section between the inner shelf and the shoulder. The edge ring includes a recess between the shoulder and the inner shelf. The edge ring defines an inner portion that is sized and shaped to support a substrate. The shoulder is sized and shaped to abut against the support to position the annular section at a gap from the support.

In one or more embodiments, a method of processing a substrate for semiconductor manufacturing is provided. The method includes positioning a substrate in a processing volume of a chamber, heating the substrate, and performing an epitaxial operation on the substrate. Positioning a substrate includes disposing a substrate on an edge ring. The edge ring includes an annular section, and a shoulder abutting against the support to position the annular section at a gap from the support to separate the substrate from the support.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of scope, for the disclosure may admit to other equally effective embodiments.

FIG. 1 is a schematic cross-sectional side view of a processing apparatus, according to one or more embodiments.

FIG. 2 is a schematic cross-sectional side view of the processing apparatus shown in FIG. 1, according to one or more embodiments.

FIG. 3 is a schematic enlarged view of the processing apparatus including the chamber kit shown in FIG. 1, according to one or more embodiments.

FIGS. 4A and 4B are schematic axonometric exploded top and bottom views of the chamber kit shown in FIG. 1, according to one or more embodiments.

FIG. 5 is a schematic cross-sectional side view of a processing apparatus, according to one or more embodiments.

FIG. 6 is a schematic enlarged view of the processing apparatus including the chamber kit shown in FIG. 5, according to one or more embodiments.

FIGS. 7A and 7B are schematic axonometric top and bottom views of the plate assembly shown in FIG. 5, according to one or more embodiments.

FIG. 8 is a schematic block diagram view of a method of processing substrates for semiconductor manufacturing, according to one or more embodiments.

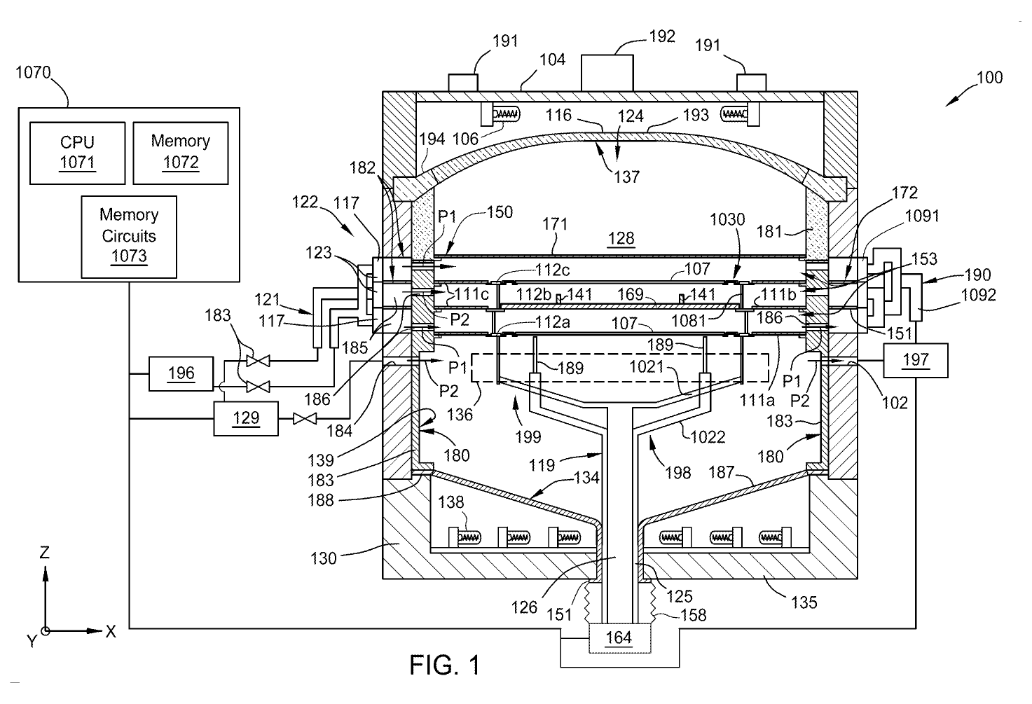

Some Figures, such as FIGS. 1, 2, and 5, omit hatching from one or more components for visual clarity purposes.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to processing chambers, related methods, and process kits with multi-section substrate supports for semiconductor manufacturing. In one or more embodiments, a processing chamber includes a chamber body, one or more heat sources, a support, and an edge ring that enhances deposition uniformity by reducing regions adjacent components with larger thermal masses.

The subject matter described herein can be used to process a single substrate at a time or two or more substrates simultaneously.

The disclosure contemplates that terms such as “couples,” “coupling,” “couple,” and “coupled” may include but are not limited to bonding, embedding, welding, fusing, melting together, interference fitting, threading, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

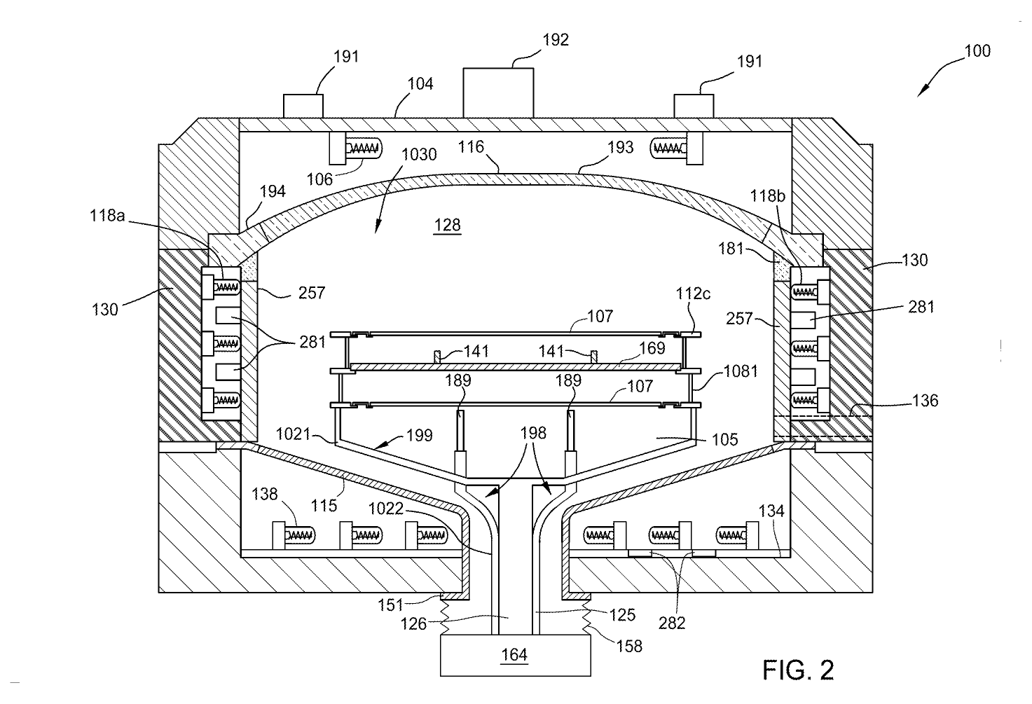

FIG. 1 is a schematic cross-sectional side view of a processing chamber 100, according to one or more embodiments. The side heat sources 118a, 118b shown in FIG. 2 are not shown in FIG. 1 for visual clarity purposes. The processing chamber 100 includes a processing chamber having a chamber body 130 that defines an internal volume 124. The internal volume 124 includes a processing volume 128.

A chamber kit 150 is positioned in the processing volume 128 and at least partially supported by a substrate support assembly 119 (such as a pedestal assembly). The chamber kit 150 includes a first plate 171, and a plurality of levels that support a plurality of substrates 107 (two are shown) for simultaneous processing (e.g., epitaxial deposition). The present disclosure contemplates that the plate 171 can be omitted. In the implementation shown in FIG. 1, the chamber kit 150 supports two substrates. The chamber kit 150 can support other numbers of substrates, including but not limited to three substrates 107, four substrates 107, six substrates 107, or eight or more substrates 107. The processing chamber 100 includes an upper window 116, such as a dome, disposed between a lid 104 and the processing volume 128. The upper window 116 includes a process surface 137 that partially defines the processing volume 128.

The processing chamber 100 includes a lower window 115 disposed below the processing volume 128. One or more upper heat sources 106 are positioned above the processing volume 128 and the upper window 116. The one or more upper heat sources 106 can be radiant heat sources such as lamps, for example halogen lamps. The one or more upper heat sources 106 are disposed between the upper window 116 and the lid 104. The upper heat sources 106 are positioned to facilitate uniform heating of the substrates 107. One or more lower heat sources 138 are positioned below the processing volume 128 and the lower window 115. The one or more lower heat sources 138 can be radiant heat sources such as lamps, for example halogen lamps. The lower heat sources 138 are disposed between the lower window 115 and a floor 134 of the internal volume 124. The lower heat sources 138 are positioned to facilitate uniform heating of the substrates 107.

The present disclosure contemplates that other heat sources may be used (in addition to or in place of the lamps) for the various heat sources described herein. For example, resistive heaters, light emitting diodes (LEDs), and/or lasers may be used for the various heat sources described herein.

The upper and lower windows 116, 115 may be transparent to the infrared radiation, such as by transmitting at least 80% (such as at least 95%) of infrared radiation. The upper and lower windows 116, 115 may be a quartz material (such as a transparent quartz). In one or more embodiments, the upper window 116 includes an inner window 193 and outer window supports 194. The inner window 193 may be a thin quartz window. The outer window supports 194 support the inner window 193 and are at least partially disposed within a support groove. In one or more embodiments, the lower window 115 includes an inner window 187 and outer window supports 188. The inner window 187 may be a thin quartz window. The outer window supports 188 support the inner window 187.

The substrate support assembly 119 is disposed in the processing volume 128. One or more liners 180 are disposed in the processing volume 128 and surround the substrate support assembly 119. The one or more liners 180 facilitate shielding the chamber body 130 from processing chemistry in the processing volume 128. The chamber body 130 is disposed at least partially between the upper window 116 and the lower window 115. The one or more liners 180 are disposed between the processing volume 128 and the chamber body 130. The one or more liners 180 include an upper liner 181 and one or more lower liners 183. In one or more embodiments, the one or more lower liners 183 include a first lower liner 139.

The processing chamber 100 includes one or more gas inject passages 182 formed in the chamber body 130 and in fluid communication with the processing volume 128, and one or more gas exhaust passages 172 (a plurality is shown in FIG. 1) formed in the chamber body 130 opposite the one or more gas inject passages 182. The one or more gas exhaust passages 172 are in fluid communication with the processing volume 128. Each of the one or more gas inject passages 182 and one or more gas exhaust passages 172 are formed through one or more sidewalls of the chamber body 130 and through the one or more liners 180 that line the one or more sidewalls of the chamber body 130.

Each gas inject passage 182 includes a gas channel 185 formed in the chamber body 130 and one or more gas openings 186 (one is shown in FIG. 1) formed in the one or more liners 180. One or more supply conduit systems are in fluid communication with the one or more gas inject passages 182. In FIG. 1, an inner supply conduit system 121 and an outer supply conduit system 122 are in fluid communication with a plurality of gas inject passages 182. The inner supply conduit system 121 includes an inner gas box 123 mounted to the chamber body 130 and in fluid communication with an inner set of the gas inject passages 182. The outer supply conduit system 122 includes a plurality of outer gas boxes 117 mounted to the chamber body 130 and in fluid communication with an outer set of the gas inject passages 182. The present disclosure contemplates that a variety of gas supply systems (e.g., supply conduit system(s), gas inject passages, and/or gas boxes different than what is shown in FIG. 1) may be used.

The processing chamber 100 includes a chamber kit 150. The chamber kit 150 includes a plurality of pre-heat rings 111a-111c positioned outwardly of the substrates 107 and the first plate 171. Three pre-heat rings 111a-111c are shown in FIG. 1. Other numbers (such as two or four) of the pre-heat rings 111 may be used. The chamber kit 150 divides the processing volume into a plurality of flow levels 153 (three flow levels are shown in FIG. 1). In one or more embodiments, the chamber kit 150 includes at least two (such as at least three) flow levels 153. The one or more gas inject passages 182 are positioned as a plurality of inject levels such that respective gas inject passage 182 corresponds to one of the plurality of inject levels. Each inject level aligns with a respective flow level 153. The pre-heat rings 111a-111c are coupled to and/or at least partially supported by the one or more liners 180. In one or more embodiments, the pre-heat rings 111a-111c respectively include a complete ring or one or more ring segments, such as a C-ring segment.

The chamber kit 150 includes a plurality of curved supports 112a-112c. A first curved support 112a is configured to support one of the substrates 107. A second curved support 112b is spaced from the first curved support 112a support and is configured to support a second plate 169. A third curved support 112c is spaced from the first curved support 112a and the second curved support 112b and the support and is configured to support the other of the substrates 107. The chamber kit 150 also includes one or more support rod structures 1081 (a plurality is shown) that support the curved supports 112a-112c. The one or more support rod structures 1081 sized and shaped to extend between the curved supports 112a-112c. In one or more embodiments, the curved supports 112a-112c respectively include a complete ring or one or more ring segments, such as a C-ring segment.

During operations (such as during an epitaxial deposition operation), one or more process gases P1 are supplied to the processing volume 128 through the outer supply conduit system 122, and through the one or more gas inject passages 182. The one or more process gases P1 are supplied from one or more gas sources 196 in fluid communication with the one or more gas inject passages 182. Each of the gas inject passages 182 is configured to direct the one or more processing gases P1 in a generally radially inward direction towards the chamber kit 150. As such, in one or more embodiments, the gas inject passages 182 may be part of a cross-flow gas injector. The flow(s) of the one or more process gases P1 can be divided into at least some of the plurality of flow levels 153. For at least the uppermost flow level 153 (or a single flow level 153—if a single flow level 153 is used), the one or more process gases P1 can be guided (using the second plate 171) along a streamlined flow path such that diversive flow away from the uppermost substrate 107 (or a single substrate 107—if a single substrate 107 is used) is reduced or eliminated.

The processing chamber 100 includes an exhaust conduit system 190. The one or more process gases P1 can be exhausted through exhaust gas openings formed in the one or more liners 180, exhaust gas channels formed in the chamber body 130, and then through exhaust gas boxes 1091. The one or more process gases P1 can flow from exhaust gas boxes 1091 and to an optional common exhaust box 1092, and then out through a conduit using one or more pump devices 197 (such as one or more vacuum pumps).

The one or more processing gases P1 can include, for example, purge gases, cleaning gases, and/or deposition gases. The deposition gases can include, for example, one or more reactive gases carried in one or more carrier gases. The one or more reactive gases can include, for example, silicon and/or germanium containing gases (such as silane (SiH₄), disilane (Si₂H₆), dichlorosilane (SiH₂Cl₂), and/or germane (GeH₄)), chlorine containing etching gases (such as hydrogen chloride (HCl)), and/or dopant gases (such as phosphine (PH₃) and/or diborane (B₂H₆)). The one or more purge gases can include, for example, one or more of argon (Ar), helium (He), nitrogen (N₂), hydrogen chloride (HCl), and/or hydrogen (H₂).

Purge gas P2 supplied from a purge gas source 129 is introduced to a bottom region 105 of the internal volume 124 through one or more purge gas inlets 184 formed in the sidewall of the chamber body 130. The purge gas P2 can also be supplied through the inner supply conduit system 121 and over the second plate 169 positioned between the two substrates 107.

The one or more purge gas inlets 184 are disposed at an elevation below the one or more gas inject passages 182. If the one or more liners 180 are used, a section of the one or more liners 180 may be disposed between the one or more gas inject passages 182 and the one or more purge gas inlets 184. The one or more purge gas inlets 184 are configured to direct the purge gas P2 in a generally radially inward direction. The one or more purge gas inlets 184 may be configured to direct the purge gas P2 in an upward direction. During a film formation process, the substrate support assembly 119 is located at a position that can facilitate the purge gas P2 to flow below the substrate 107. The purge gas P2 exits the bottom region 105 and is exhausted out of the processing chamber 100 through one or more purge gas exhaust passages 102 located on the opposite side of the processing volume 128 relative to the one or more purge gas inlets 184.

The substrate support assembly 119 includes a first lift frame 199 and a second lift frame 198 disposed at least partially about the first lift frame 199. The first lift frame 199 includes one or more first arms 1021 that lift and lower the chamber kit 150, the first plate 171, and the second plate 169. A plurality of lift pins 189 are coupled to the second lift frame 198 by arms 1022 of the second lift frame 198. Continued lowering of and/or lifting of the second lift frame 198 initiates contact of the lift pins 189 with a substrate 107, the chamber kit 150, and/or the second plate 169 such that the lift pins 189 raise the substrate 107 , the chamber kit 150, and/or the second plate 169. A bottom region 105 of the processing chamber 100 is defined between the floor 134 and the substrate 107. In some embodiments the lift pins 189 can be configured to abut against—and be lifted from—the arms 1022.

A first shaft 126 of the first lift frame 199, a second shaft 125 of the second lift frame 198, and a section 151 of the lower window 115 extend through a port formed in a bottom 135 of the chamber body 130 and the floor 134. Each shaft 125, 126 is respectively coupled to one or more respective motors 164, which are configured to independently raise, lower, and/or rotate the substrates 107 and the second plate 169 using the first lift frame 199, and to independently raise and lower the lift pins 189 using the second lift frame 198. The first lift frame 199 includes the first shaft 126 and the one or more first arms 1021 configured to support the substrate supports 112 and the second plate 171.

The second lift frame 198 includes the second shaft 125 and the plurality of second arms 1022 configured to interface with and support the lift pins 189. A bellows assembly 158 circumscribes and encloses a portion of the shafts 125, 126 disposed outside the chamber body 130 to facilitate reduced or eliminated vacuum leakage outside the chamber body 130.

An opening 136 (a substrate transfer opening) is formed through the one or more sidewalls of the chamber body 130. The opening 136 may be used to transfer the second plate 169 and/or the substrates 107 to or from the curved supports 112a-112c, e.g., in and out of the internal volume 124. In one or more embodiments, the opening 136 includes a slit valve. In one or more embodiments, the opening 136 may be connected to any suitable valve that enables the passage of substrates therethrough. The opening 136 is shown in ghost in FIGS. 1 and 2 for visual clarity purposes.

The processing chamber 100 may include one or more sensors 191, 192, 282, such as temperature sensors (e.g., optical pyrometers) or other metrology sensors, which measure temperatures (or other parameters) within the processing chamber 100 (such as on the surfaces of the upper window 116, the first plate 171, the second plate 169, the curved supports 112a-112c, the pre-heat rings 111a-111c, and/or the substrates 107). The one or more sensors 191, 192 are disposed on the lid 104. The one or more sensors 282 (e.g., lower pyrometers)—which are shown in FIG. 2—are disposed on a lower side of the lower window 115. The one or more sensors 282 can be disposed adjacent to and/or on the bottom 135 of the chamber body 130.

In one or more embodiments, upper sensors 191, 192 are oriented toward a top of the second plate 171. In one or more embodiments, side sensors 281 (e.g., side temperature sensors) are oriented toward one or more of the curved supports 112a-112c and/or the pre-heat rings 111a-111c. In one or more embodiments, lower sensors 282 are oriented toward a bottom of the chamber kit 150 (such as a lower surface of the first lift frame 199, a bottom of the plate second 171, and/or a bottom of the first pre-heat ring 111a.

The processing chamber 100 includes a controller 1070 configured to control the processing chamber 100 or components thereof. For example, the controller 1070 may control the operation of components of the processing chamber 100 using a direct control of the components or by controlling controllers associated with the components. In operation, the controller 1070 enables data collection and feedback from the respective chambers to coordinate and control performance of the processing chamber 100.

The controller 1070 generally includes a central processing unit (CPU) 1071, a memory 1072, and support circuits 1073. The CPU 1071 may be one of any form of a general purpose processor that can be used in an industrial setting. The memory 1072, or non-transitory computer readable medium, is accessible by the CPU 1071 and may be one or more of memory such as random access memory (RAM), read only memory (ROM), floppy disk, hard disk, or any other form of digital storage, local or remote. The support circuits 1073 are coupled to the CPU 1071 and may include cache, clock circuits, input/output subsystems, power supplies, and the like.

The various methods (such as the method 1300) and operations disclosed herein may generally be implemented under the control of the CPU 1071 by the CPU 1071 executing computer instruction code stored in the memory 1072 (or in memory of a particular processing chamber) as, e.g., a software routine. When the computer instruction code is executed by the CPU 1071, the CPU 1071 controls the components of the processing chamber 100 to conduct operations in accordance with the various methods and operations described herein. In one or more embodiments, the memory 1072 (a non-transitory computer readable medium) includes instructions stored therein that, when executed, cause the methods (such as the method 800) and operations (such as the operations 802-810) described herein to be conducted. The controller 1070 can be in communication with the heat sources, the gas sources, and/or the vacuum pump(s) of the processing chamber 100, for example, to cause a plurality of operations to be conducted.

The first plate 171, the second plate 169 and/or the one or more liners 180 (such as the upper liner 181 and/or the one or more lower liners 183), are formed of one or more of quartz (such as transparent quartz, e.g. clear quartz; opaque quartz, e.g. white quartz, or grey quartz; and/or black quartz), silicon carbide (SiC), graphite coated with SiC, and/or one or more ceramics.

The second plate 169 of the processing chamber 100 includes a plurality of columns 141 extending relative to a side of the second plate 169. In such an embodiment, the lower substrate 107 can firstly be lifted from the first curved support 112a such that the lower substrate 107 can be transferred out of the processing chamber 100.

The lift pins 189 can then contact the second plate 169 and lift the second plate 169 from the second curved support 112b such that the columns 141 contact the upper substrate 107 and lift the upper substrate 107 from the third curved support 112c such that the upper substrate 107 can be transferred out of the processing chamber 100.

FIG. 2 is a schematic cross-sectional side view of the processing chamber 100 shown in FIG. 1, according to one or more embodiments. The cross-sectional view shown in FIG. 2 is rotated by 55 degrees relative to the cross-sectional view shown in FIG. 1.

The processing chamber 100 includes one or more side heat sources 118a, 118b (e.g., side lamps, side resistive heaters, side LEDs, and/or side lasers, for example) positioned outwardly of the processing volume 128. One or more second side heat sources 118b are opposite one or more first side heat sources 118a across the processing volume 128. The side heat sources 118a, 118b are operable and configured to heat the processing volume 128.

In FIG. 2, the pre-heat rings 111a-111c are not shown for visual clarity purposes. In addition to the one or more sensors 191, 192 positioned above the processing volume 128 and above the second plate 171, the processing chamber 100 may include one or more sensors 281, such as temperature sensors (e.g., optical pyrometers) or other metrology sensors, which measure temperatures (or other parameters) within the processing chamber 100. A plurality of windows 257—if used—can be disposed in gaps between or formed in the one or more liners 180 (such as the upper liner 181 and/or the one or more lower liners 183). The one or more sensors 281 are side sensors (e.g., side pyrometers) that are positioned outwardly of the processing volume 128, outwardly of the pre-heat rings 111a-111c (shown in FIG. 1), and outwardly of the plurality of windows 257. The one or more sensors 281 can be radially aligned, for example, with the plurality of windows 257 (as shown in FIG. 2).

The one or more side sensors 281 (such as one or more pyrometers) can be used to measure temperatures within the processing volume 128 from respective sides of the processing volume 128. The side sensors 281 are arranged in a plurality of sensor levels (two sensor levels are shown in FIG. 2). In one or more embodiments, the number of sensor levels is equal to the number of heat source levels. Each side sensor 281 can be oriented horizontally or can be directed (e.g., oriented downwardly at an angle) toward the substrate 107 and the substrate support 112 of a respective level of the cassette 1030.

The present disclosure contemplates that the side heat sources 118a, 118b, the windows 257, and/or the side sensors 281 can be omitted.

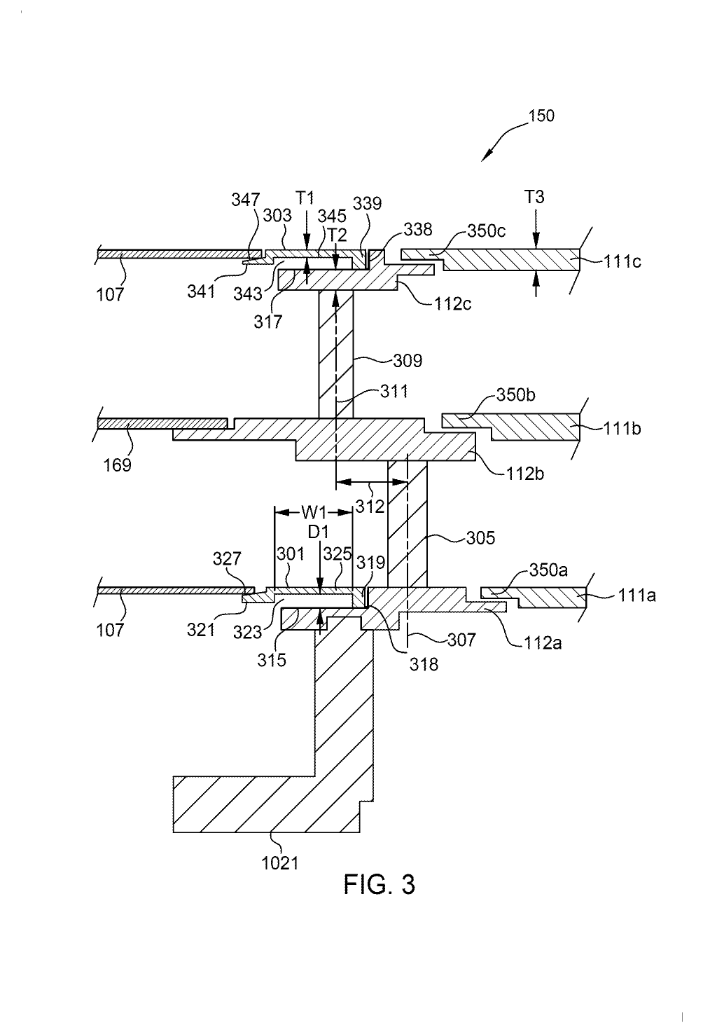

FIG. 3 is a schematic enlarged view of the chamber kit 150 shown in FIG. 1. The first support 112a at least partially supports (e.g., at an outer periphery of) a first edge ring 301. the first edge ring 301 is sized and shaped for disposition on the first support 112a. The third support 112c at least partially supports (e.g., at an outer periphery of) a second edge ring 303. The supports 112a-112c are disposed radially inward of the pre-heat rings 111a-111c. The edge rings 301, 303

The supports 112a-112c are sized and shaped for positioning within the corresponding pre-heat rings 111a-111c. The chamber kit 150 also includes one or rod structures 305, 309 that support the curved supports 112a-112c. The one or rod structures 305, 309 are sized and shaped to extend between the curved supports 112a-112c. The first support 112a includes a first post structure 305 of the one or more posts. The second support 112b includes a second post structure 309 of the one or more posts. The first post structure 305 includes a central axis 307. The second post structure 309 includes a central axis 311.

The first rod structure 305 is disposed radially outward of the second rod structure 309. The central axis 307 of the first post structure 305 is disposed radially outward of the central axis 311 of the second rod structure 309 by a distance 312. The distance 312 is about 1 millimeter to 25 millimeters. The first post structure 305 supports the second support 112b. The second rod structure 309 supports the third support 112c.

The first support 112a includes a shelf 315. The first edge ring 301 is disposed on the shelf 315. The third support 112c includes a shelf 317. The second edge ring 303 is disposed on the shelf 315.

The edge rings 301, 303 respectively include a shoulder 319, 339 abutting the support 112a, 112c, an inner shelf 321, 341 extending radially inward, a recess 323, 343 between the shoulder 319, 339 and the inner shelf 321, 341, an annular section 325, 345 extending radially inward. The recess 323, 343 is an annular recess having a width W1 of about 1 millimeter to about 3.5 millimeters. The recess 323, 343 is disposed between the respective edge ring 301, 303 and respective support 112a, 112c. The shoulder 319, 339 abuts against the support 112a, 112c to position the annular section 325, 345 at a gap from the shelf 315, 317 of the support 112a, 112c. The gap between the annular section 325, 345 and the shelf 315, 317 has a distance D1. The recess 323, 343 is at least part of the gap having the distance D1. The distance D1 is about 1 millimeter to about 3.5 millimeters, such as about 1.5 millimeters to about 3.0 millimeters.

The respective shoulders 319, 339 of the edge rings 301, 303 form a respective offset 318, 338 from the respective support 112a, 112c. The offset 318, 338 is a radial distance (e.g., width) between the respective shoulders 319, 339 of the edge rings 301, 303 and a portion of the respective support 112a, 112c extending perpendicularly from the respective shelf 315, 317.

In one or more embodiments, the respective shelf 315, 317 extends radially inward at least part (e.g., at least half) the respective annular section 325, 345. For example, the respective shelf 315, 317 is disposed below at least half of the respective annular section 325, 345. As another example, the respective shelf 315, 317 extends radially inward by 50% or more of the width W1.

In one or more embodiments, the pre-heat rings 111a-111c respectively include an extension 350a-350c. The respective extension 350a-350c extends over part of the respective support 112a-112c to facilitate a virtual seal between the respective extension 350a-350c and the respective support 112a-112c. The respective shelf 315, 317 is disposed opposite of the respective extensions 350a, 350c, such that the shelf 315, 317 extends radially inward and away from the respective extension 350a-350c.

The inner shelf 321, 341, the annular section 325, 345, and the shoulder 319, 339 have a thickness T1 that is less than 1.0 mm. In one or more embodiments, the thickness T1 is less than 0.6 mm, such as about 0.5 mm. In one or more embodiments, the inner shelf 321, 341, the annular section 325, 345, and the shoulder 319, 339 are formed of graphite coated with silicon carbide, and 90 mil of the thickness T1 is the silicon carbide coating. The present disclosure contemplates other values than those recited herein, such as for the thickness of the silicon carbide coating.

In one or more embodiments, which can be combined with other embodiments, the thickness T1 is less than half of a thickness T2 of the respective shelf 315, 317. In one or more embodiments, a ratio of the thickness T1 to the thickness T2 of the respective shelf 315, 317 is about 1:2 or less, such as about 1:2 to about 1:10.

In one or more embodiments, which can be combined with other embodiments, the thickness T1 is less than half of a thickness T3 of the respective pre-heat rings 111a-111c. In one or more embodiments, the ratio of thickness T1 to the thickness T3 of the respective pre-heat rings 111a-111c is about 1:2 or less, such as about 1:2 to about 1:10.

In one or more embodiments, which can be combined with other embodiments, the inner shelf 321, 341 has a tapered surface 327, 347. The tapered surface 327, 347 may angle toward the respective first support 112a or third support 112c or away from the respective first support 112a or third support 112c (as shown). The taper can be linear (as shown) or curved (such as rounded). The respective substrate 107 is disposed on the respective tapered surface 327, 347. The inner shelf 321, 341 of the edge rings 301, 303 each define an inner portion sized and shaped to support the respective substrate 107.

The edge rings 301, 303 and supports 112a-112c respectively include a silicon carbide coating. In one or more embodiments, the edge rings 301303 and supports 112a-112c respectively are formed of graphite coated with silicon carbide.

The edge rings 301, 303 respectively include a material having a specific heat of 730 J/Kg-K or less and a density of 2,500 Kg/m³ or less. In one or more embodiments, the density is within a range of 2,200 Kg/m³ to 2,300 Kg/m³. In one or more embodiments, the specific heat is within a range of 700 J/Kg-K to 720 J/Kg-K. In one or more embodiments, the edge rings 301, 303 respectively include a coating formed over the material. The edge rings 301, 303 respectively include a mass of less than 100 grams.

The edge rings 301, 303 and the supports 112a-112c facilitate low thermal mass while maintaining mechanical strength for support and thermal strain. For example, the low thermal mass facilitates reduced heat flow away from the substrate 107, enhancing processing uniformity. The low thermal mass can reduce or eliminate, for example, edge roll-off and deposition slip lines. The low thermal mass also facilitates process adjustability, such as thermal adjustability.

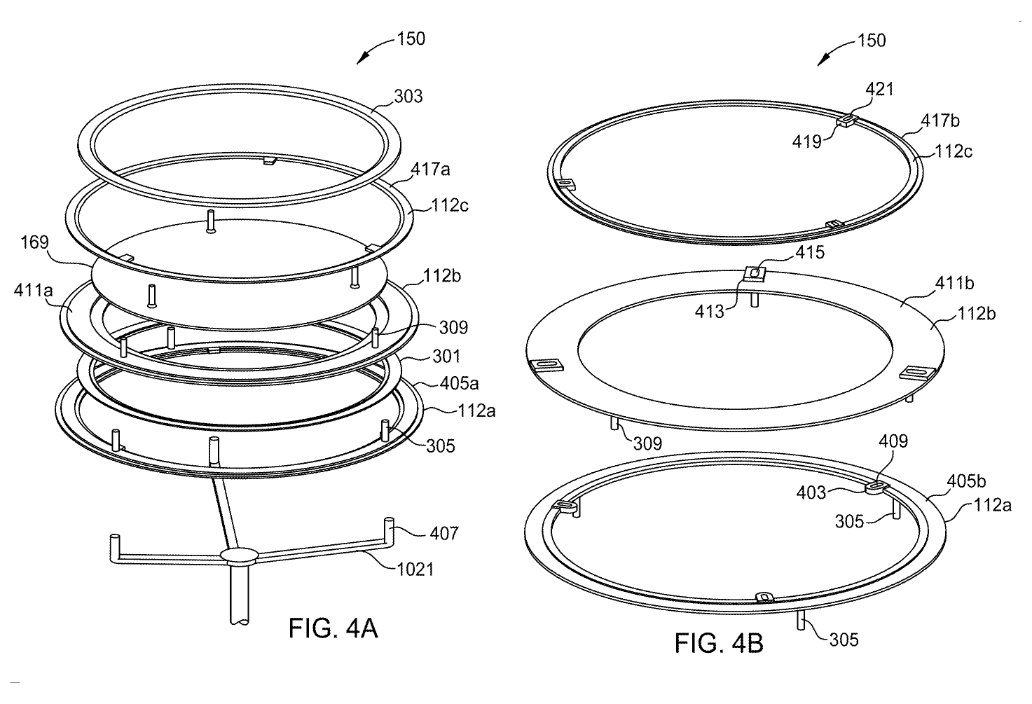

FIGS. 4A and 4B are schematic axonometric exploded top and bottom views of a chamber kit 150. The chamber kit 150 is similar to the chamber kit 150 shown in FIGS. 1 and 3, according to one or more embodiments. The second plate 169 is disposed between the first edge ring 301 and the second edge ring 303. The second support 112b at least partially supports (e.g., at an outer periphery of) the second plate 169.

The first support 112a includes a top surface 405a, a lower surface 405b, and a plurality of support tabs 403 extending relative to the lower surface 405b. The plurality of support tabs 403 include respective receptacle openings 409 configured to receive posts 407 of the one or more first arms 1021. The plurality of support tabs 403 are disposed radially and azimuthally offset from the first post structure 305. For example, the plurality of support tabs 403 are disposed azimuthally offset about 1° to about 15° from the first post structures 305.

The second support 112b includes a top surface 411a, a lower surface 411b, and a plurality of support features 413 extending relative to the lower surface 411b. The plurality of support features 413 include respective receptacle openings 415 configured to receive first post structures 305 of the first support 112a. The plurality of support features 413 are disposed radially and azimuthally offset from the second post structure 309. For example, the support feature 413 is disposed azimuthally offset about 1° to about 15° from second post structure 309.

The third support 112c includes a top surface 417a, a lower surface 417b, and a plurality of support tabs 419 disposed on the lower surface 417b. The plurality of support tabs 419 include receptacle openings 421 configured to receive second rod structures 309 of the second support 112b. The plurality of support tabs 419 are disposed radially and azimuthally offset from the second rod structures 309. For example, the plurality of support tabs 419 are disposed azimuthally offset about 1° to about 15° from the second rod structures 309.

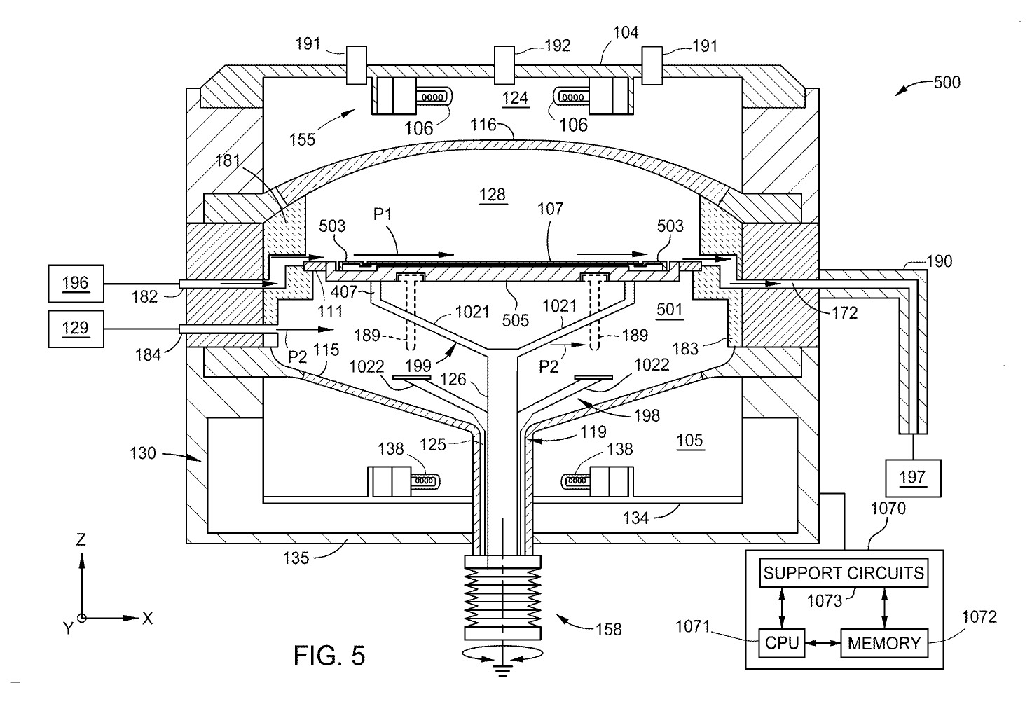

FIG. 5 is a schematic cross-sectional side view of a processing chamber 500, according to one or more embodiments. The processing chamber 500 is similar to the processing chamber 100 shown in FIG. 1, and includes one or more of the aspects, features, components, properties, and/or operations thereof. Some components in processing chamber 100 may be omitted from the processing chamber 500. For example, the cassette 1030 (FIG. 1) can be omitted, and the processing chamber 500 includes one of the flow dividers 111 (e.g., a pre-heat ring) shown in FIG. 1. The one or more upper heat sources 106 are positioned above the processing volume 128 and the upper window 116 within an upper cavity 155 defined by the lid 104. The internal volume 124 includes the upper cavity 155.

In one or more embodiments, which can be combined with other embodiments, the processing chamber 500 includes the first lift frame 199 that supports a plate assembly 501 configured to support a substrate 107. The plate assembly 501 includes a support disc 505, such as a susceptor. The support disc 505 of the plate assembly 501 is coupled to and/or rests on the posts 407 of the one or more first arms 1021. The plate assembly 501 includes an edge ring 503. The edge ring 503 is disposed in the process volume 128 and disposed on the support disc 505. The edge ring 503 is similar to the edge ring 301 of FIG. 3. The substrate 107 is disposed on the edge ring 503. As shown, the subject matter described herein can be used to process a single substrate 107 at a time in the processing chamber 500. During operations (such as during an epitaxial deposition operation), one or more process gases P1 are supplied to the processing volume 128 through the one or more gas inject passages 182 and flow over the substrate 107. The process gas P1 is then exhausted through one or more gas exhaust passages 172 of the exhaust conduit system 190.

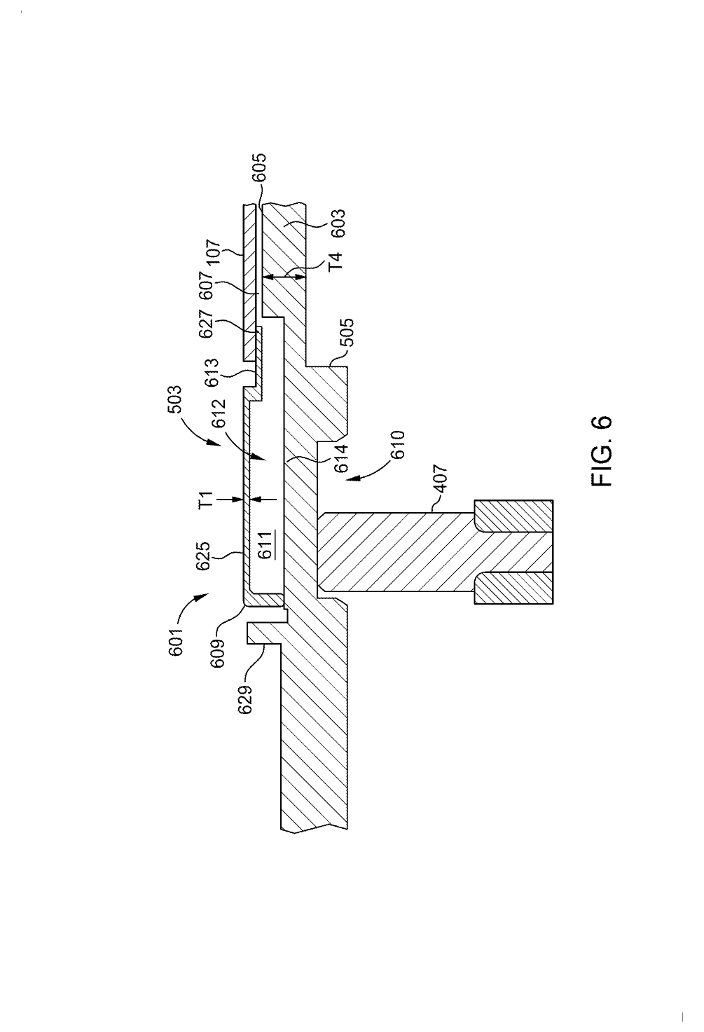

FIG. 6 is a schematic enlarged view of the plate assembly 501 shown in FIG. 5.

The support disc 505 includes a channel 601 surrounding a central region 603. The channel 601 is a recess surrounding the central region 603. A shoulder 629 of the support disc 505 defines an outer diameter of the channel 601. The shoulder 629 extends vertically from the support disc 505. A top surface 605 of the central region 603 and the substrate 107 form a gap 607 between the top surface 605 and the substrate 107.

The edge ring 503 is disposed in the channel 601 of the support disc 505. The support disc 505 at least partially supports (e.g., an outer region of) the edge ring 503. The support disc 505 includes a receptacle opening 610 sized and shaped to receive the one or more first arms 1021 of the lift frame 199.

The edge ring 503 includes a shoulder 609 abutting the support disc 505, an inner shelf 613 extending radially inward, a recess 611 between the shoulder 609 and the inner shelf 613, and an annular section 625 extending radially inward. The recess 611 is between the annular section 625 and the support disc 505. The edge ring 503 can include one or more aspects, features, and/or properties of the first edge ring 301 and/or the second edge ring 303. The inner shelf 613 and the shoulder 609 have the thickness T1 that is less than 1.0 mm. A distance between the annular section 625 of the edge ring 503 and the support disc 505 at the recess 611 is greater than a distance of the gap 607 between the top surface 605 of the support disc 505 and the substrate 107.

In one or more embodiments, which can be combined with other embodiments, the thickness T1 is less than half of a thickness T4 of the central region 603. In one or more embodiments, the ratio of thickness T1 to the thickness T4 of the central region 603 is about 1:2 or less, such as about 1:2 to about 1:10.

In one or more embodiments, the support disc 505 includes a groove 612. The groove 612 is an annular recess and the edge ring 503 is disposed therein. The edge ring 503 is disposed on a groove surface 614. The groove surface 614 defines the width of the groove 612. The groove surface 614 forms a plane that is about parallel to a plane formed by the top surface 605 of the support disc 505. The plane of the top surface 605 is disposed between the plane of the groove surface 614 of the groove 612 and the plane of the annular section 625 of the edge ring 503.

In one or more embodiments, which can be combined with other embodiments, the shoulder 609 of the edge ring 503 and the shoulder 629 of the support disc 505 define a gap. For example, the shoulder 609 of the edge ring 503 is disposed radially inward of the 0.5 millimeters or more from the shoulder 629 of the support disc 505.

In one or more embodiments, which can be combined with other embodiments, the inner shelf 613 has a tapered surface 627. The tapered surface 627 may angle toward (as shown) the support disc 505 or away from support disc 505. The substrate 107 is disposed on the tapered surface 627. The taper can be linear (as shown) or curved (such as rounded).

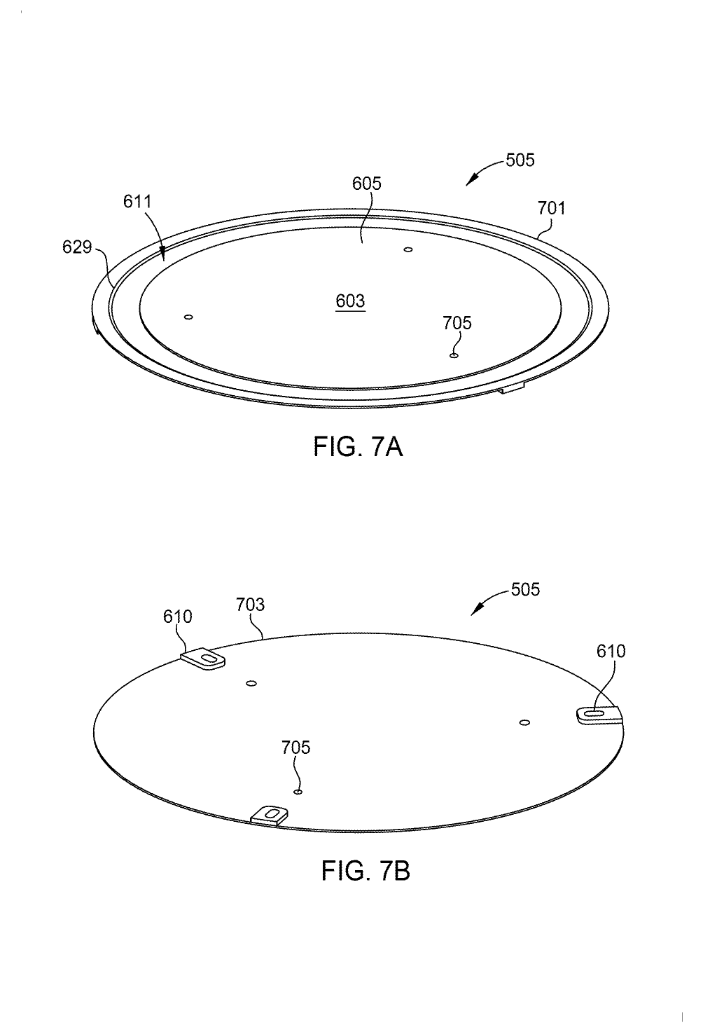

FIGS. 7A and 7B are schematic axonometric top and bottom views of the support disc 505.

The support disc 505 includes a top surface 701, a lower surface 703, and the receptacle openings 610 disposed on the lower surface 703. The support disc 505 also includes lift pin holes 705 aligned the receptacle openings 610. The lift pin holes 705 extend from the top surface 701 to the lower surface 703.

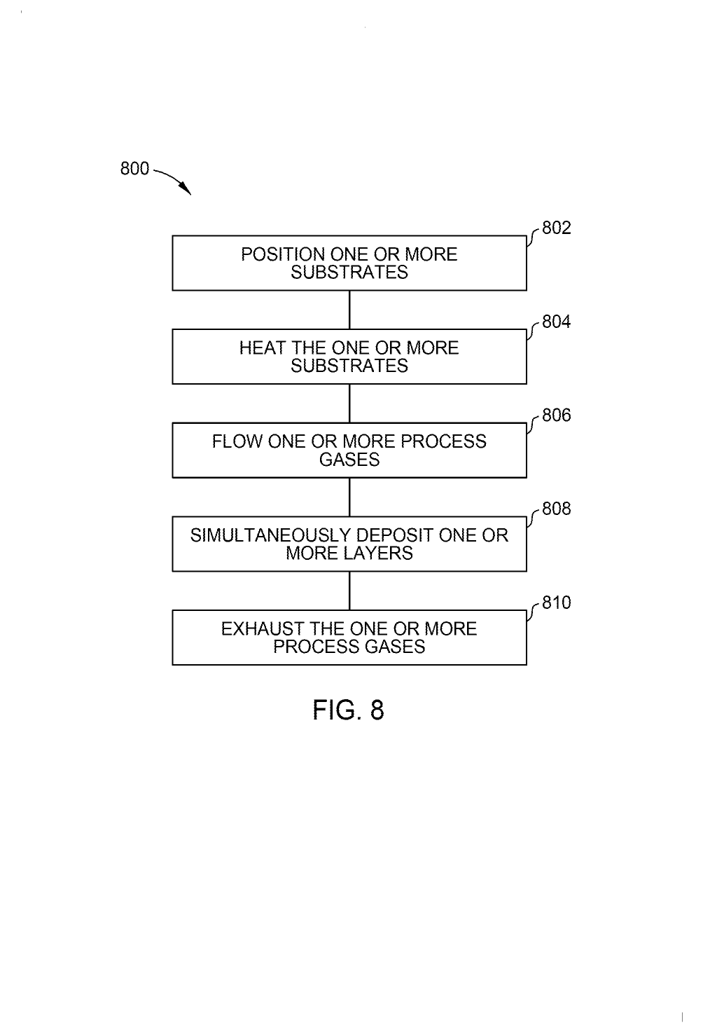

FIG. 8 is a schematic block diagram view of a method 800 of processing substrates for semiconductor manufacturing, according to one or more embodiments.

Operation 802 of the method 800 includes positioning one or more substrates in a processing volume of a chamber. The one or more substrates are disposed on corresponding one or more edge rings within the processing volume of a chamber. In one or more embodiments, the substrate is separated from a support by the edge ring.

Operation 804 includes heating the one or more substrates. It is contemplated that operation 804 may occur prior to, subsequent to, and/or concurrent with operation 806. By incorporating the edge rings described above, the lower thermal mass enhances deposition uniformity of subsequently deposited layers on the substrate 107. The uniformity is enhanced because the thermal masses of the support and the edge ring reduces or eliminates heat flow away from the edge ring and away from the processed substrate.

Operation 806 includes flowing one or more process and/or inert gases into the processing volume 128.

Operation 808 includes simultaneously depositing or baking one or more layers respectively on the one or more substrates. For example, the depositing includes performing an epitaxial operation on the substrate. In one or more embodiments, the baking includes hydrogen (H2) to remove moisture and/or impurities from the substrate. The present disclosure contemplates that the depositing of operation 808 can be replaced with etching the substrate, pre-cleaning the substrate, or cleaning the processing chamber.

Operation 810 includes exhausting the one or more process or inert gases from the processing volume. During the flowing of operation 806 and/or the exhausting of operation 810, the one or more process or inert gases can follow the flow paths described herein (such as the flow paths described in relation to FIGS. 1 and 2).

Benefits of the present disclosure include enhanced deposition uniformity of subsequently deposited layers on a substrate; reduced or eliminated shadowing effects; modularity in chamber application; more uniform gas activation; temperature uniformity (e.g., temperature uniformity in an outer region of the substrate); more uniform film growth and/or dopant concentration; and increased throughput. As an example, the reduced thermal mass of the edge ring allows for two substrates in a process chamber, thereby enhancing through-put, while reducing the thermal load additional structure may impart, and thereby reducing potential sources of non-uniformity.

It is contemplated that one or more aspects disclosed herein may be combined. As an example, one or more aspects, features, components, operations and/or properties of the processing chamber 100; the controller 1070; the process kit 150, the supports 112a, 112b, 112c, the support disc 505, pre-heat rings 111a-111c, the first plate 171, the second plate 169 and/or the method 800 may be combined.

While the foregoing is directed to embodiments of the present disclosure, other and further embodiments of the disclosure may be devised without departing from the basic scope thereof, and the scope thereof is determined by the claims that follow.

What is claimed is:

1. A processing chamber applicable for semiconductor manufacturing, comprising:
a chamber body comprising:
a processing volume,
one or more gas inject passages formed in the chamber body, and
one or more gas exhaust passages formed in the chamber body;
one or more heat sources operable to heat the processing volume;
a support disposed in the processing volume; and
an edge ring supported at least partially by the support, the edge ring defining an inner portion, the inner portion sized and shaped to support a substrate, the edge ring comprising:
an annular section, and
a shoulder abutting against the support to position the annular section at a gap from the support.

2. The processing chamber of claim 1, wherein the support is a first curved support sized and shaped for positioning within a first pre-heat ring, and the processing chamber further comprises:
a second curved support spaced from the first curved support, the second curved support sized and shaped for positioning within a second pre-heat ring;
a second edge ring supported at least partially by the second curved support, the second edge ring having a thickness that is less than half of a thickness of the second pre-heat ring; and
a plate disposed between the first curved support and the second curved support.

3. The processing chamber of claim 1, wherein the support includes a disc comprising a groove, the edge ring disposed in the groove.

4. The processing chamber of claim 3, wherein the support comprises a top surface of a central region, the top surface disposed between a groove surface of the groove and the annular section of the edge ring.

5. The processing chamber of claim 4, wherein the edge ring further comprises:
an inner shelf extending radially inward, a distance between the top surface and the inner shelf being less than a distance between the annular section and groove surface.

6. The processing chamber of claim 5, wherein the inner shelf and the shoulder respectively have a thickness that is less than 1.0 mm.

7. The processing chamber of claim 1, wherein the support comprises a shelf, the edge ring disposed on the shelf, and a thickness of the annular section of the edge ring less than a thickness of the shelf.

8. A chamber kit applicable for semiconductor manufacturing, comprising:
a support; and
an edge ring sized and shaped for disposition on the support, the edge ring comprising:
a shoulder;
an inner shelf extending radially inward of the shoulder, the inner shelf defining an inner portion, the inner portion sized and shaped to support a substrate;
an annular section between the inner shelf and the shoulder, the shoulder sized and shaped to abut against the support to position the annular section at a gap from the support; and
a recess between the shoulder and the inner shelf.

9. The chamber kit of claim 8, wherein the support is a first curved support, the edge ring is a first edge ring, and the chamber kit further comprises:
a second curved support;
a second edge ring sized and shaped for disposition on the second curved support; and
a plate disposed between the first edge ring and the second edge ring.

10. The chamber kit of claim 9, wherein the shoulder of the first edge ring is sized and shaped to abut against a shelf of the first curved support.

11. The chamber kit of claim 9, wherein the plate is disposed on a third curved support, the third curved support disposed between the first curved support and the second curved support.

12. The chamber kit of claim 11, wherein a post of the first curved support is radially aligned and disposed radially outward of a post of the third curved support.

13. The chamber kit of claim 9, wherein a third curved support comprises a receptacle opening sized and shaped to receive a post of the first curved support.

14. The chamber kit of claim 9, wherein first edge ring comprises a material having a specific heat of 730 J/Kg-K or less and a density of 2,500 Kg/m³ or less.

15. The chamber kit of claim 14, wherein the material includes graphite coated with silicon carbide.

16. The chamber kit of claim 8, wherein the support comprises a shelf, the edge ring disposed thereon, the shelf extending radially inward by at least half a width of the annular section.

17. The chamber kit of claim 9, wherein the edge ring has a mass of less than 100 grams.

18. The chamber kit of claim 8, wherein the support further comprises a shelf, the shelf extending radially inward by at least half of a width of the annular section of the edge ring.

19. A method of processing a substrate, the method comprising:
positioning a substrate in a processing volume of a chamber, positioning a substrate comprises disposing a substrate on an inner portion of an edge ring, the edge ring comprising:
an annular section, and
a shoulder abutting against a support to position the annular section at a gap from the support to separate the substrate from the support;
heating the substrate; and
performing an epitaxial operation on the substrate.

20. The method of claim 19, wherein the substrate is disposed on an inner shelf of the edge ring, the edge ring comprises:
a recess between a shoulder and the inner shelf; and
an annular section between the inner shelf and the shoulder, the annular section, the inner shelf and the shoulder partially defining the recess.
